(19) United States
(12) Patent Application Publication
(10) Pub. No.: US 2025/0048587 A1
(43) Pub. Date: Feb. 6, 2025

(54) COLD PLATE AND METHOD OF MANUFACTURING COLD PLATE

(71) Applicant: FURUKAWA ELECTRIC CO., LTD., Tokyo (JP)

(72) Inventors: Yuki MACHIDA, Tokyo (JP); Shuta HIKICHI, Tokyo (JP); Hirofumi AOKI, Tokyo (JP); Kenya KAWABATA, Tokyo (JP)

(21) Appl. No.: 18/780,518

(22) Filed: Jul. 23, 2024

(30) Foreign Application Priority Data
Jul. 31, 2023 (JP) 2023-124339

(51) Int. Cl. H05K 7/20

(52) U.S. Cl. CPC H05K 7/20254

(57) ABSTRACT

Provided is a cold plate that can improve cooling efficiency and simultaneously suppress an increase in size in a thickness direction. A heat-transfer-medium flow space 2 is formed between a heat dissipation surface 13 of a base plate 10 and a cover plate 20. The base plate 10 has a plurality of heat transfer portions 14 that are provided so as to protrude from the heat dissipation surface 13 toward the cover plate 20 and that transfer, to a heat-transfer medium flowing through the heat-transfer-medium flow space 2, heat released from the heat dissipation surface 13. A heat transfer joining portion 32 that joins at least a portion of tips of the heat transfer portions 14 to the cover plate 20 is formed between at least the portion of the tips of the plurality of heat transfer portions 14 and a surface of the cover plate 20 facing the heat-transfer-medium flow space 2.

This application is based on and claims the benefit of priority from Japanese Patent Application No. 2023-124339, filed on 31 Jul. 2023, the content of which is incorporated herein by reference.

### BACKGROUND OF THE INVENTION

### Field of the Invention

The present disclosure relates to a cold plate used in cooling an object to be cooled such as an electronic component, and a method of manufacturing the cold plate.

### Related Art

A cold plate described in Japanese Unexamined Patent Application (Translation of PCT Application), Publication No. 2013-506996 is known as a conventional cold plate. This cold plate has therein a heat-transfer-medium flow space, through which a heat-transfer medium flows, and releases, to a heat-transfer medium flowing through the heat-transfer-medium flow space, heat released from an object to be cooled, and includes: a base plate provided with, on a surface, a heat absorbing surface for absorbing the heat released from the object to be cooled and provided with, on another surface, a heat dissipation surface for releasing, to the heat-transfer medium flowing through the heat-transfer-medium flow space, the heat absorbed by the heat absorbing surface; and a cover plate covering the heat dissipation surface of the base plate. The base plate has a plurality of heat transfer portions that are provided so as to protrude from the heat dissipation surface toward the cover plate and that transfer, to the heat-transfer medium flowing through the heat-transfer-medium flow space, the heat released from the heat dissipation surface.

For the cold plate described in Japanese Unexamined Patent Application (Translation of PCT Application), Publication No. 2013-506996, in a case in which a gap is formed between tips of the plurality of the heat transfer portions and a surface of the cover plate facing a heat-transfer-medium flow space the heat-transfer medium flowing through the heat-transfer-medium flow space flows more easily through the gap between the tips of the plurality of the heat transfer portions and the cover plate than the gaps between the heat transfer portions. For this reason, in the cold plate described in Japanese Unexamined Patent Application (Translation of PCT Application), Publication No. 2013-506996, the heat-transfer medium that has flowed through the heat-transfer-medium flow space flows out of the heat-transfer-medium flow space without sufficiently absorbing heat from the heat transfer portions, and thus it is not possible to improve the cooling efficiency.

To address the above situation, Japanese Unexamined Patent Application, Publication No. 2019-186297 describes a cold plate in which the flow of a heat-transfer medium through a gap between tips of a plurality of heat transfer portions and a surface of a cover plate facing the heat-transfer-medium flow space is restricted by disposing a joining member between the tips of the plurality of the heat transfer portions and the surface of the cover plate facing the heat-transfer-medium flow space, thereby improving cooling efficiency.
Patent Document 1: Japanese Unexamined Patent Application (Translation of PCT Application), Publication No. 2013-506996
Patent Document 2: Japanese Unexamined Patent Application, Publication No. 2019-186297

### SUMMARY OF THE INVENTION

However, in the cold plate described in Japanese Unexamined Patent Application, Publication No. 2019-186297, due to the joining member disposed between the tips of the plurality of the heat transfer portions and the surface of the cover plate facing the heat-transfer-medium flow space, the height dimension of the plurality of the heat transfer portions is small, and the contact area between the heat transfer portions and the heat-transfer medium flowing through the heat-transfer-medium flow space is small, whereby there is a possibility of the cooling capacity being lowered. Further, in a case in which the heat transfer portions in the cold plate described in Japanese Unexamined Patent Application, Publication No. 2019-186297 have a height dimension that enables the cold plate to exhibit a necessary cooling capacity, the dimension of the entire cold plate in the thickness direction increases.

An object of the present disclosure is to provide a cold plate that can improve cooling efficiency and simultaneously suppress an increase in size in the thickness direction, and a method of manufacturing the cold plate.

A cold plate according to the present disclosure that has therein a heat-transfer-medium flow space, through which a heat-transfer medium flows, and that releases, to the heat-transfer medium flowing through the heat-transfer-medium flow space, heat absorbed from an object to be cooled, the cold plate including: a base plate provided with, on a surface, a heat absorbing surface that absorbs heat released from the object to be cooled and provided with, on another surface, a heat dissipation surface that releases, to the heat-transfer medium flowing through the heat-transfer-medium flow space, the heat absorbed by the heat absorbing surface; and a cover plate that covers the heat dissipation surface of the base plate. The heat-transfer-medium flow space is formed between the heat dissipation surface of the base plate and the cover plate. The base plate has a plurality of heat transfer portions that are provided so as to protrude from the heat dissipation surface toward the cover plate and that transfer, to the heat-transfer medium flowing through the heat-transfer-medium flow space, the heat released from the heat dissipation surface. A heat transfer joining portion that joins at least a portion of tips of the plurality of heat transfer portions to the cover plate is formed between at least the portion of the tips of the plurality of heat transfer portions and a surface of the cover plate facing the heat-transfer-medium flow space.

In the cold plate according to the present disclosure, it is preferable that each of the plurality of heat transfer portions is configured as a fin that extends along a flow direction of the heat-transfer medium flowing through the heat-transfer-medium flow space.

Further, in the cold plate according to the present disclosure, it is preferable that the base plate has a base-side joining portion provided so as to extend in a circumferential direction of an outer periphery of the base plate, the cover plate has a cover-side joining portion provided so as to extend in the circumferential direction of an outer periphery of the cover plate, and a seal joining portion that seals the heat-transfer-medium flow space is formed between the base-side joining portion and the cover-side joining portion.

Further, in the cold plate according to the present disclosure, it is preferable that the base plate and the cover plate are each made of copper, a copper alloy, aluminum, an aluminum alloy, stainless steel, or a stainless-steel alloy.

A method of manufacturing the cold plate according to the present disclosure that has therein a heat-transfer-medium flow space, through which a heat-transfer medium flows, and that releases, to the heat-transfer medium flowing through the heat-transfer-medium flow space, heat absorbed from an object to be cooled, the method including: a plate stacking step of stacking, on a base plate, a cover plate that covers a heat dissipation surface, the base plate being provided with, on a surface, a heat absorbing surface that absorbs heat released from the object to be cooled, being provided with, on another surface, the heat dissipation surface that releases, to the heat-transfer medium flowing through the heat-transfer-medium flow space, heat absorbed by the heat absorbing surface, and being provided with a plurality of heat transfer portions that are provided so as to protrude from the heat dissipation surface toward the cover plate and that transfer, to the heat-transfer medium flowing through the heat-transfer-medium flow space, the heat released from the heat dissipation surface; and a heat transfer joining step of joining, to a surface of the cover plate facing a heat-transfer-medium flow space, at least a portion of tips of the plurality of heat transfer portions by laser welding in a state in which the cover plate has been stacked on the base plate in the plate stacking step.

It is preferable that the method of manufacturing the cold plate according to the present disclosure further includes: a heat transfer portion forming step of forming the plurality of heat transfer portions into fin shapes that extend along a flow direction of the heat-transfer medium flowing through the heat-transfer-medium flow space.

It is preferable that the method of manufacturing the cold plate according to the present disclosure further includes: a base-side joining portion forming step of forming a base-side joining portion that is provided so as to extend in a circumferential direction of an outer periphery of the base plate, a cover-side joining portion forming step of forming a cover-side joining portion that is provided so as to extend in the circumferential direction of an outer periphery of the cover plate, and a seal joining step of sealing the heat-transfer-medium flow space by joining the base-side joining portion formed in the base-side joining portion forming step and the cover-side joining portion formed in the cover-side joining portion forming step to each other.

It is preferable that in the method of manufacturing the cold plate according to the present disclosure, in the seal joining step, the base-side joining portion and the cover-side joining portion are joined to each other by brazing, diffusion bonding, friction stir welding, or pressure welding.

According to the present disclosure, it is possible to reduce or eliminate the gap between the tips of the heat transfer portions and the surface of the cover plate facing the heat-transfer-medium flow space, and thus it is possible to reduce a flow amount of the heat-transfer medium adjacent to the cover plate in the heat-transfer-medium flow space and increase the flow amount of the heat-transfer medium between adjacent heat transfer portions, and it is possible to improve the cooling efficiency. Further, it is possible to suppress an increase in size in the thickness direction, and thus it is possible to reduce the space required for installation of the cold plate, reduce materials used to manufacture the cold plate, and reduce the weight of the cold plate.

### BRIEF DESCRIPTION OF THE DRAWINGS

FIG. 1 is an overall perspective view of a cold plate according to an embodiment of the present disclosure;

FIG. 2 is an exploded perspective view of the cold plate according to the embodiment of the present disclosure, as viewed from a cover plate side;

FIG. 3 is an exploded perspective view of the cold plate according to the embodiment of the present disclosure, as viewed from a base plate side;

FIG. 4 is a side view of a main part of the base plate according to the embodiment of the present disclosure;

FIG. 5 is a plan view of the cold plate according to the embodiment of the present disclosure;

FIG. 6 is a bottom view of the cold plate according to the embodiment of the present disclosure;

FIG. 7 is a side cross-sectional view, and illustrates a method of manufacturing the cold plate according to the embodiment of the present disclosure;

FIG. 8 is a side cross-sectional view of the cold plate, and illustrates the method of manufacturing the cold plate according to the embodiment of the present disclosure;

FIG. 9 is a front cross-sectional view of the cold plate, and illustrates the method of manufacturing the cold plate according to the embodiment of the present disclosure;

FIG. 10 is a side cross-sectional view of the cold plate, and illustrates the method of manufacturing the cold plate according to the embodiment of the present disclosure;

FIGS. 11A to 11C are plan views of the cold plate, and illustrate other examples of an arrangement of heat transfer joining portions;

FIG. 12 is a side cross-sectional view of the cold plate, and illustrates another example of heat transfer portions;

FIGS. 13A and 13B are plan views of the cold plate, and illustrate other examples of a flow path of a heat-transfer medium formed in a heat-transfer-medium flow space;

FIGS. 14A to 14E are side cross-sectional views of the cold plate, and illustrate other examples of a shape of the heat transfer joining portion; and

FIGS. 15A and 15B are side views of the base plate, and illustrate other examples of a shape of a tip portion of each heat transfer portion.

### DETAILED DESCRIPTION OF THE INVENTION

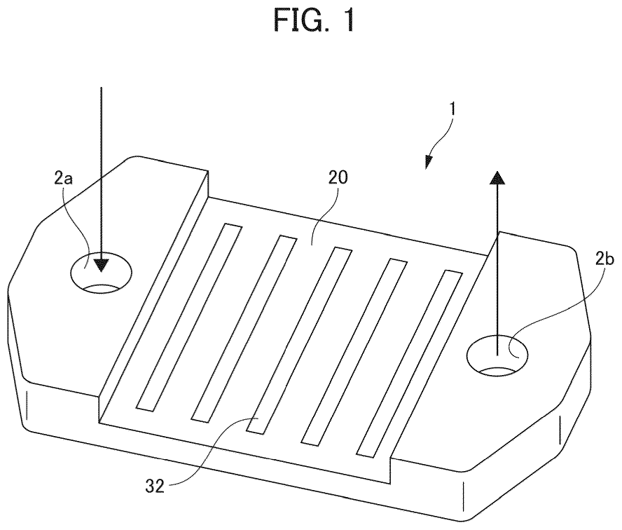

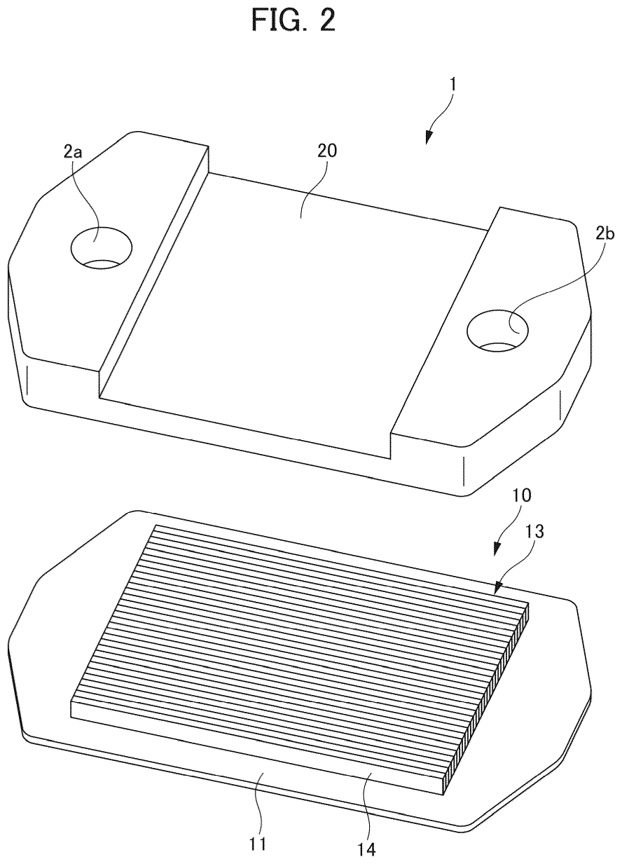

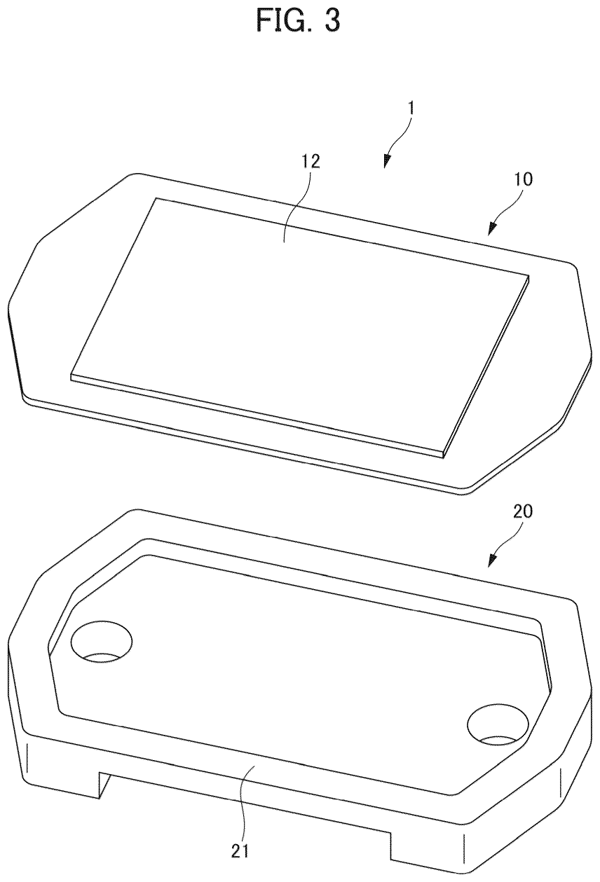

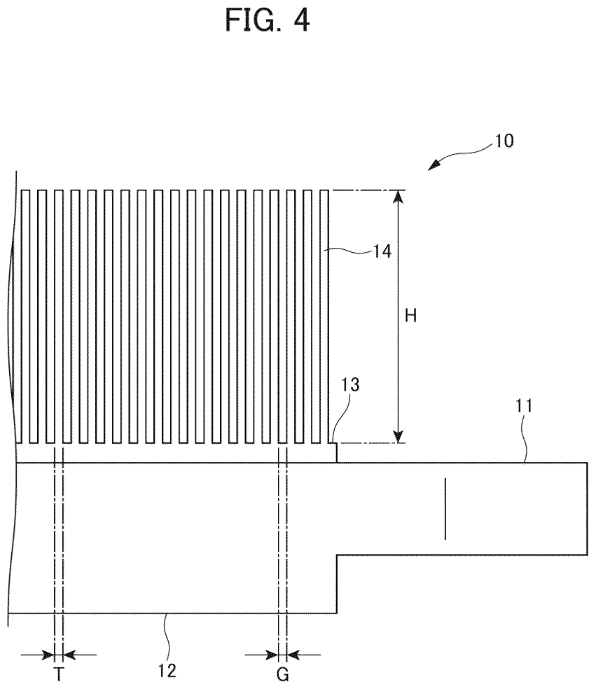

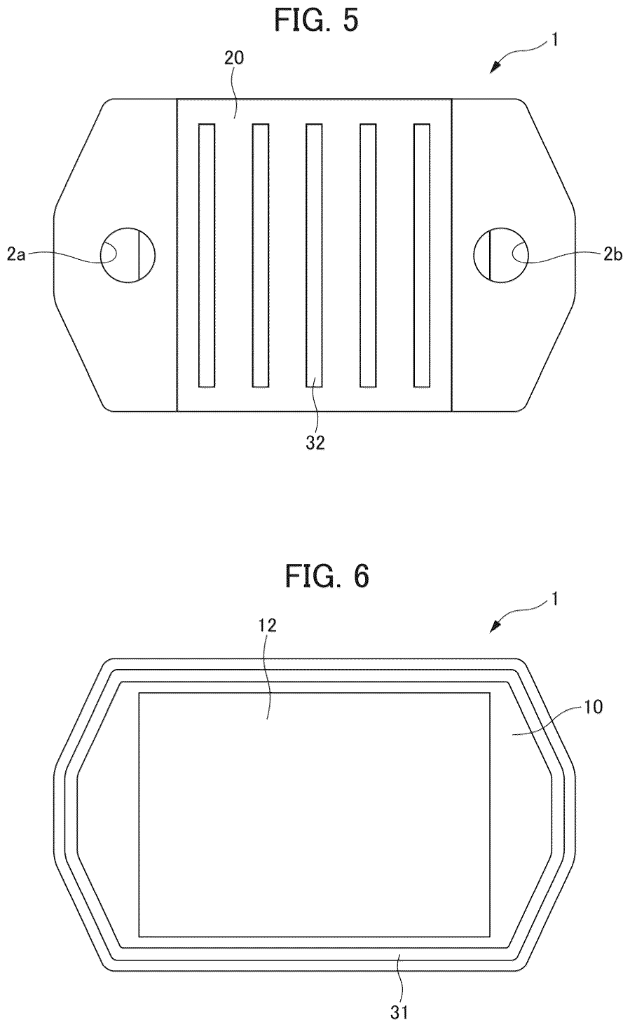

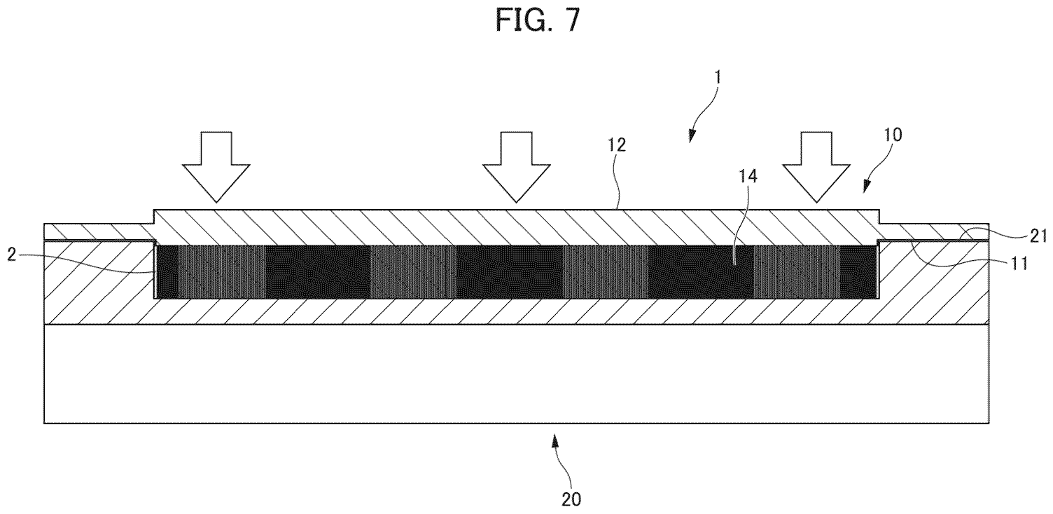

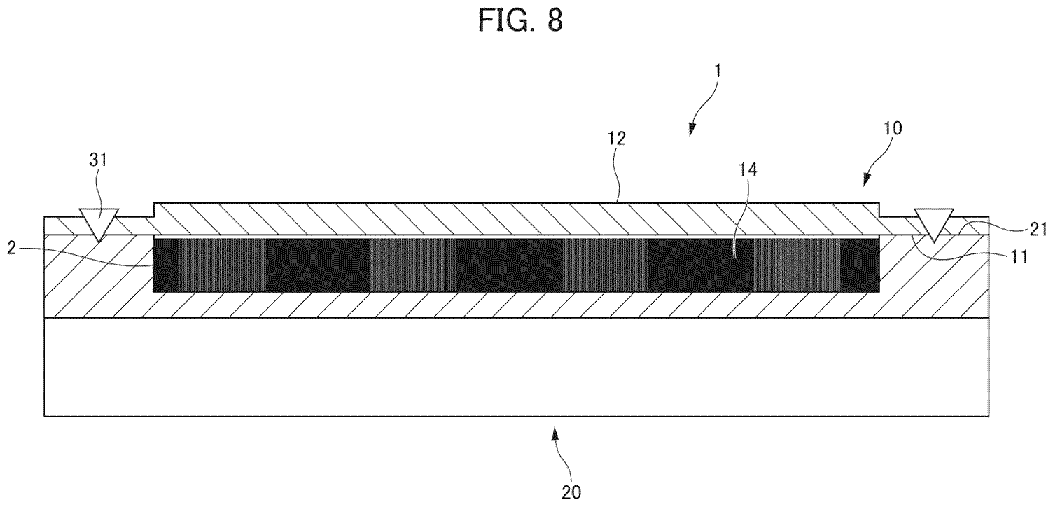

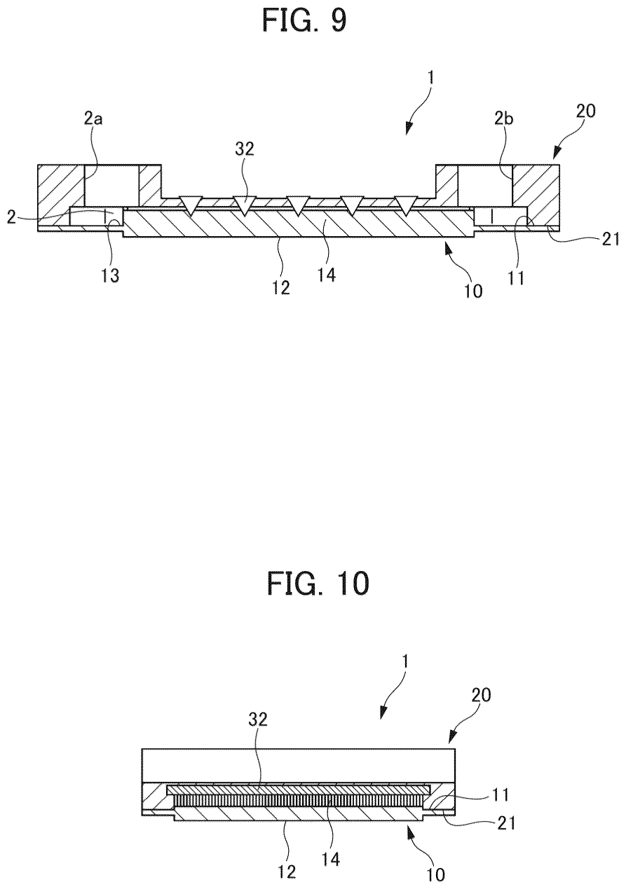

FIGS. 1 to 10 illustrate an embodiment of the present disclosure. FIG. 1 is an overall perspective view of a cold plate, FIG. 2 is an exploded perspective view of the cold plate as viewed from a cover plate side, FIG. 3 is an exploded perspective view of the cold plate as viewed from a base plate side, FIG. 4 is a side view of a main part of the base plate, FIG. 5 is a plan view of the cold plate, FIG. 6 is a bottom view of the cold plate, FIG. 7 is a side cross-sectional view describing a method of manufacturing the cold plate, FIG. 8 is a side cross-sectional view of the cold plate and illustrates the method of manufacturing the cold plate, FIG. 9 is a front cross-sectional view of the cold plate and illustrates the method of manufacturing the cold plate, and FIG. 10 is a side cross-sectional view of the cold plate and illustrates the method of manufacturing the cold plate.

The cold plate 1 of the present embodiment is used, for example, to cool an object to be cooled such as an electronic component that generates heat. As illustrated in FIGS. 1 and 9, the cold plate 1 is provided therein with a heat-transfer medium inlet 2a through which a heat-transfer medium flows into a heat-transfer-medium flow space 2, and a heat-transfer medium outlet 2b through which the heat-transfer medium that has flowed through the heat-transfer-medium flow space 2 flows out. The cold plate 1 is used while a heat-transfer medium supply pipe (not shown) is connected to the heat-transfer medium inlet 2a and a heat-transfer medium discharge pipe (not shown) is connected to the heat-transfer medium outlet 2b. The cold plate 1 causes the heat-transfer medium that has been cooled to flow into the heat-transfer-medium flow space 2 via the heat-transfer medium inlet 2a, causes the heat-transfer medium in the heat-transfer-medium flow space 2 to absorb heat released from the object to be cooled, and causes the heat-transfer medium that has absorbed the heat in the heat-transfer-medium flow space 2 to flow out of the heat-transfer-medium flow space 2 via the heat-transfer medium outlet 2b. Here, for example, water is used as the heat-transfer medium.

As illustrated in FIG. 2 and FIG. 3, the cold plate 1 includes a base plate 10 and a cover plate 20.

The base plate 10 is a substantially rectangular plate-shaped member made of a metal that has a high thermal conductivity, such as copper, a copper alloy, aluminum, an aluminum alloy, stainless steel, or a stainless-steel alloy. As illustrated in FIGS. 2 and 3, the base plate 10 includes a base-side joining portion 11 to which the cover plate 20 is joined, a heat absorbing surface 12 that absorbs the heat released from the object to be cooled, a heat dissipation surface 13 that releases, to the heat-transfer medium flowing through the heat-transfer-medium flow space 2, the heat absorbed by the heat absorbing surface 12, and a plurality of heat transfer portions 14 that are provided so as to protrude from the heat dissipation surface 13, and transfer, to the heat-transfer medium flowing through the heat-transfer-medium flow space 2, the heat released from the heat dissipation surface 13.

The base-side joining portion 11 is formed, in a circumferential direction, along an outer periphery of a surface of the base plate 10 facing the cover plate 20.

The heat absorbing surface 12 is a surface on which the object to be cooled is placed, and is provided on an outer side of the base plate 10 in a stacking direction.

The heat dissipation surface 13 is a flat surface positioned inside an inner periphery of the base-side joining portion 11, and the entirety of the heat dissipation surface 13 protrudes further toward the cover plate 20 than the base-side joining portion 11.

The plurality of heat transfer portions 14 are formed together with the heat dissipation surface 13 by, for example, skiving the surface of the base plate 10 facing the cover plate 20. Each of the plurality of heat transfer portions 14 is configured as a fin that protrudes from the heat dissipation surface 13 and extends in a flow direction of the heat-transfer medium flowing through the heat-transfer-medium flow space 2. As illustrated in FIG. 4, each of the plurality of heat transfer portions 14 has, for example, a height dimension H of 3 mm, a thickness dimension T of 0.1 mm, and an interval G of 0.1 mm between adjacent heat transfer portions 14.

The cover plate 20 is a plate-like member made of a metal having a high thermal conductivity, such as copper, a copper alloy, aluminum, an aluminum alloy, stainless steel, or a stainless-steel alloy. The cover plate 20 has a cover-side joining portion 21 that is provided so as to extend along the outer periphery of the cover plate 20 in the circumferential direction and that joins to the base plate 10 in a state in which the cover plate is superposed on the base plate 10, and a portion inside an inner periphery of the cover-side joining portion 21 is formed in a concave shape. Upon the base-side joining portion 11 and the cover-side joining portion 21 joining to each other, the heat-transfer-medium flow space 2 is formed between the heat dissipation surface 13 of the base plate 10 and the cover plate 20. Further, in the cover plate 20, the heat-transfer medium inlet 2a is formed at an end portion in a longitudinal direction, and the heat-transfer medium outlet 2b is formed at another end portion in the longitudinal direction.

Here, a seal joining portion 31 that seals the heat-transfer-medium flow space 2 is formed between the base-side joining portion 11 of the base plate 10 and the cover-side joining portion 21 of the cover plate 20. As illustrated in FIGS. 6 and 8, the seal joining portion 31 is formed by performing laser welding along the base-side joining portion 11 from the base plate 10 side in a state in which the base plate 10 and the cover plate 20 are stacked on each other.

Further, heat transfer joining portions 32 that join at least a portion of the tips of the plurality of heat transfer portions 14 and the cover plate 20 are formed between at least the portion of the tips of the plurality of heat transfer portions 14 and a surface of the cover plate 20 facing the heat-transfer-medium flow space 2. As illustrated in FIGS. 5, 9, and 10, each heat transfer joining portion 32 is formed by performing laser welding from the cover plate 20 side in a state in which the base plate 10 and the cover plate 20 are stacked on each other. In the present embodiment, as illustrated in FIG. 5, each heat transfer joining portion 32 linearly extends in a width direction of the heat-transfer-medium flow space 2 in a direction orthogonal to the flow direction of the heat-transfer medium flowing in the heat-transfer-medium flow space 2 and is formed at five positions that are spaced apart from each other in the flow direction of the heat-transfer medium. It should be noted that, for example, even in the configuration illustrated in FIG. 5, each heat transfer joining portion 32 formed so as to extend in a straight line may be in a state in which not all the tips of the heat transfer portions 14 that are positioned on the heat-transfer-medium flow space 2 side of the heat transfer joining portion 32 are joined to the base plate 20, that is, in a state in which some of the tips of the heat transfer portions 14 that correspond to the straight-line portion are joined to the base plate 20 and the remainder of the tips of the heat transfer portions 14 are in contact with the base plate 20.

The cold plate 1 that is configured as described above causes the heat-transfer medium to flow into the heat-transfer-medium flow space 2 via the heat-transfer medium inlet 2a while the object to be cooled is placed on the heat absorbing surface 12 of the base plate 10 and causes the heat-transfer medium that has flowed through the heat-transfer-medium flow space 2 to flow out of the heat-transfer-medium flow space 2 via the heat-transfer medium outlet 2b.

During the process described above, the heat released from the object to be cooled is absorbed by the heat absorbing surface 12 of the base plate 10, transferred from the heat absorbing surface 12 to the heat dissipation surface 13 and the plurality of heat transfer portions 14, and released to the heat-transfer medium flowing through the heat-transfer-medium flow space 2. With this configuration, it is possible for the object to be cooled to release the heat to the heat-transfer medium flowing through the heat-transfer-medium flow space 2 and be continuously cooled.

Further, the heat-transfer medium that has flowed into the heat-transfer-medium flow space 2 sequentially flows through spaces between the plurality of heat transfer joining portions 32 that linearly extend in the width direction in a direction orthogonal to the flow direction of the heat-transfer medium and the heat dissipation surface 13, and then flows out from the heat-transfer-medium flow space 2. The heat-transfer medium flowing into the heat-transfer-medium flow space 2 flows between the heat transfer portions 14 without flowing through the gap between the tips of the plurality of heat transfer portions 14 and the cover plate 20, and efficiently absorbs the heat released from the heat transfer portions 14.

Further, a method of manufacturing the cold plate 1 described above includes the following steps.

In a base-side joining portion forming step, cutting or the like is performed so that the base-side joining portion 11 is formed so as to extend along an outer periphery of the base plate 10 in the circumferential direction and protrude less than the heat dissipation surface 13.

In a cover-side joining portion forming step, cutting or the like is performed so that the cover-side joining portion 21 is formed so as to extend along the outer periphery of the cover plate 20 in the circumferential direction.

In a heat transfer portion forming step, skiving is performed to form the plurality of heat transfer portions 14 together with the heat dissipation surface 13 of the base plate 10. The heat transfer portion forming step includes forming each of the plurality of heat transfer portions 14 into a fin shape that extends along the flow direction of the heat-transfer medium flowing through the heat-transfer-medium flow space 2.

In a plate stacking step, the cover plate 20 is stacked on the base plate 10 on which the base-side joining portion 11 has been formed in the base-side joining portion forming step and on which the plurality of heat transfer portions 14 together with the heat dissipation surface 13 have been formed in the heat transfer portion forming step.

In a plate pressing step, as illustrated in FIG. 7, the base plate 10 and the cover plate 20 that have been stacked in the plate stacking step are pressed against each other in the stacking direction to bring the tips of the plurality of heat transfer portions 14 into contact with a surface of the cover plate 20 facing the heat dissipation surface 13.

In a seal joining step, as illustrated in FIG. 8, the seal joining portion 31 is formed in the circumferential direction between the base-side joining portion 11 of the base plate 10 and the cover-side joining portion 21 of the cover plate 20 by performing laser welding on the base-side joining portion 11 in a state in which the base plate 10 and the cover plate 20 are stacked on each other.

In a heat transfer joining step, as illustrated in FIGS. 9 and 10, each heat transfer joining portion 32 is formed between the tips of a portion of the plurality of heat transfer portions 14 and the surface of the cover plate 20 facing the heat-transfer-medium flow space 2 by performing laser welding on the cover plate 20 in a state in which the base plate 10 and the cover plate 20 are joined to each other in the seal joining step.

As described above, the cold plate 1 according to the present embodiment has therein the heat-transfer-medium flow space 2, through which the heat-transfer medium flows, and that releases, to the heat-transfer medium flowing through the heat-transfer-medium flow space 2, the heat absorbed from the object to be cooled. The cold plate 1 includes: the base plate 10 provided with, on the surface, the heat absorbing surface 12 that absorbs the heat released from the object to be cooled and provided with, on the other surface, the heat dissipation surface 13 that releases, to the heat-transfer medium flowing through the heat-transfer-medium flow space 2, the heat absorbed by the heat absorbing surface 12; and the cover plate 20 that covers the heat dissipation surface 13 of the base plate 10. The heat-transfer-medium flow space 2 is formed between the heat dissipation surface 13 of the base plate 10 and the cover plate 20. The base plate 10 has the plurality of heat transfer portions 14 that are provided so as to protrude from the heat dissipation surface 13 toward the cover plate 20 and that transfer, to the heat-transfer medium flowing through the heat-transfer-medium flow space 2, the heat released from the heat dissipation surface 13. The heat transfer joining portion 32 that joins at least a portion of the tips of the plurality of heat transfer portions 14 to the cover plate 20 is formed between at least the portion of the tips of the plurality of heat transfer portions 14 and a surface of the cover plate 20 facing the heat-transfer-medium flow space 2.

Further, the present embodiment provides a method of manufacturing the cold plate 1. The method of manufacturing the cold plate 1 that has therein the heat-transfer-medium flow space 2, through which the heat-transfer medium flows, and that releases, to the heat-transfer medium flowing through the heat-transfer-medium flow space 2, the heat absorbed from the object to be cooled, includes: the plate stacking step of stacking, on the base plate 10, the cover plate 20 that covers the heat dissipation surface 13, the base plate 10 being provided with, on the surface, a heat absorbing surface 12 that absorbs the heat released from the object to be cooled, being provided with, on the other surface, the heat dissipation surface 13 that releases, to the heat-transfer medium flowing through the heat-transfer-medium flow space 2, the heat absorbed by the heat absorbing surface 12, and being provided with the plurality of heat transfer portions 14 that are provided so as to protrude from the heat dissipation surface 13 toward the cover plate 20 and that transfer, to the heat-transfer medium flowing through the heat-transfer-medium flow space 2, the heat released from the heat dissipation surface 13; and the heat transfer joining step of joining, to the surface of the cover plate 20 facing the heat-transfer-medium flow space 2, at least a portion of the tips of the plurality of heat transfer portions 14 by laser welding in a state in which the cover plate 20 has been stacked on the base plate 10 in the plate stacking step.

Due to the features described above, it is possible to reduce or eliminate the gap between the tips of the heat transfer portions 14 and the surface of the cover plate 20 facing the heat-transfer-medium flow space 2, and thus it is possible to reduce a flow amount of the heat-transfer medium adjacent to the cover plate 20 in the heat-transfer-medium flow space 2 and increase the flow amount of the heat-transfer medium between the adjacent heat transfer portions 14, and it is possible to improve the cooling efficiency. Further, it is possible to suppress an increase in size in the thickness direction, and thus it is possible to reduce the space required for installation of the cold plate 1, reduce materials used to manufacture the cold plate 1, and reduce the weight of the cold plate 1. In a case in which the heat transfer joining portion 32 is formed by laser welding, softening due to annealing does not occur, and thus it is possible to reduce a plate thickness of the cover plate 20, and thus it is possible to improve the cooling performance by reducing a thermal resistance of the cover plate 20 as well as reduce manufacturing costs of the cold plate 1 by reducing the materials used to manufacture the cold plate 1, and to reduce the weight of the cold plate 1. Further, in the case in which the heat transfer joining portions 32 are formed by laser welding, no brazing material is necessary, and thus it is possible to further reduce the manufacturing costs. Furthermore, in the case in which the heat transfer joining portions 32 are formed by laser welding, only the material of the base plate 10 and the material of the cover plate 20 are melted, and thus it is possible to suppress the occurrence of clogging due to an intrusion of a molten material into the gaps between the adjacent heat transfer portions 14, and to prevent corrosion due to inclusion of a different material, compared to the case in which a brazing material is used.

According to the cold plate 1 of the present embodiment, it is preferable that each of the plurality of heat transfer portions 14 is configured as a fin that extends along the flow direction of the heat-transfer medium flowing through the heat-transfer-medium flow space 2.

According to the method of manufacturing the cold plate 1 of the present embodiment, it is preferable that the method includes a heat transfer portion forming step of forming the plurality of heat transfer portions 14 into fin shapes that extend along the flow direction of the heat-transfer medium flowing through the heat-transfer-medium flow space 2.

Due to the features described above, it is possible to dispose the heat transfer portions 14 substantially throughout the heat-transfer-medium flow space 2 in the flow direction of the heat-transfer medium, and thus it is possible to more efficiently transfer heat from the heat transfer portions 14 to the heat-transfer medium.

According to the cold plate 1 of the present embodiment, it is preferable that the base plate 10 has the base-side joining portion 11 provided so as to extend in the circumferential direction of the outer periphery of the base plate 10, the cover plate 20 has the cover-side joining portion 21 provided so as to extend in the circumferential direction of the outer periphery of the cover plate 20, and the seal joining portion 31 that seals the heat-transfer-medium flow space 2 is formed between the base-side joining portion 11 and the cover-side joining portion 21.

According to the method of manufacturing the cold plate 1 of the present embodiment, it is preferable that the method includes the base-side joining portion forming step of forming the base-side joining portion 11 that is provided so as to extend in the circumferential direction of the outer periphery of the base plate 10, the cover-side joining portion forming step of forming the cover-side joining portion 21 that is provided so as to extend in the circumferential direction of the outer periphery of the cover plate 20, and the seal joining step of sealing the heat-transfer-medium flow space 2 by joining the base-side joining portion 11 formed in the base-side joining portion forming step and the cover-side joining portion 21 formed in the cover-side joining portion forming step to each other.

Due to the features described above, it is possible to reliably seal the heat-transfer-medium flow space 2 by joining the base-side joining portion 11 and the cover-side joining portion 21 to each other.

Further, according to the cold plate 1 of the present embodiment, it is preferable that the base plate 10 and the cover plate 20 are each made of copper, a copper alloy, aluminum, an aluminum alloy, stainless steel, or a stainless-steel alloy.

Further, according to the method of manufacturing the cold plate 1 of the present embodiment, it is preferable that in the seal joining step, the base-side joining portion 11 and the cover-side joining portion 21 are joined to each other by brazing, diffusion bonding, friction stir welding, or pressure welding.

In the above-described embodiment, an example has been described in which each of the plurality of heat transfer portions 14 is configured as a fin that has the height dimension H of 3 mm, the thickness dimension T of 0.1 mm, and the interval G of 0.1 mm between the adjacent heat transfer portions 14, but the present disclosure is not limited thereto. For each of the plurality of heat transfer portions, it is possible to arbitrarily set the height dimension H, the thickness dimension T, and the interval G between the adjacent heat transfer portions.

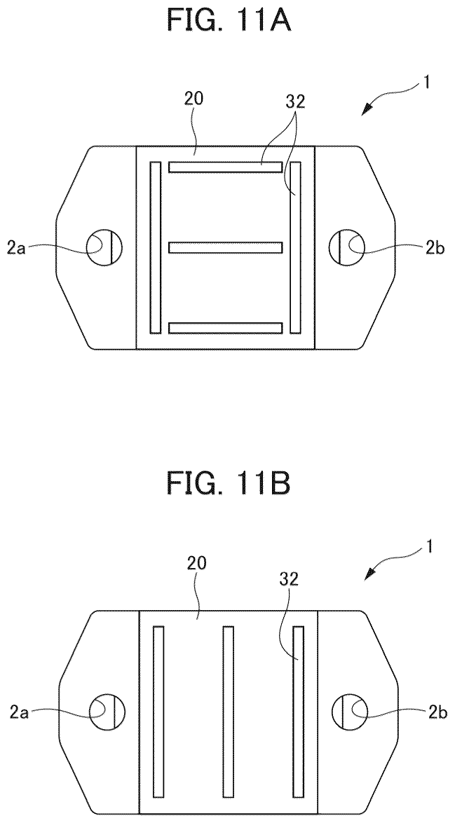

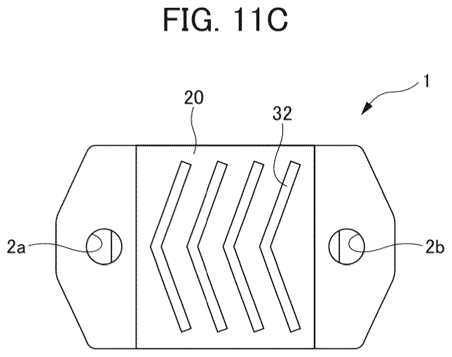

The above-described embodiment has described that each heat transfer joining portion 32 is formed so as to linearly extend in the width direction of the heat-transfer-medium flow space 2 in a direction orthogonal to the flow direction of the heat-transfer medium flowing through the heat-transfer-medium flow space 2, and formed at five positions at intervals in the flow direction of the heat-transfer medium, but the present disclosure is not limited thereto. For example, as illustrated in FIG. 11A, the heat transfer joint portion 32 may be disposed at an upstream position and at a downstream position in the flow direction of the heat-transfer medium and so as to extend in a direction orthogonal to the flow direction of the heat-transfer medium, and the heat transfer joining portions 32 that extend in the flow direction of the heat-transfer medium may be formed at positions that are central and on both sides in the width direction of the heat-transfer-medium flow space 2. Further, for example, as shown in FIG. 11B, the heat transfer joint portion 32 may be disposed at each of an upstream position, a central position, and a downstream position in the flow direction of the heat-transfer medium and so as to extend in a direction orthogonal to the flow direction of the heat-transfer medium. Furthermore, as illustrated in FIG. 11C, the heat transfer joining portions 32 that are each formed so as to bend at a central portion in the width direction of the heat-transfer-medium flow space 2 and extend, from the central portion toward both sides, obliquely downstream in the flow direction of the heat-transfer medium may be disposed at a plurality of positions in the flow direction of the heat-transfer medium. By adjusting an arrangement, an extension direction, an extension length, and the number of the heat transfer joint portions 32 to be disposed, it is possible to set the flow path of the heat-transfer medium and regulate the flow rate of the heat-transfer medium. Even providing one heat transfer joining portion 32 in the heat-transfer-medium flow space 2 makes it possible to improve the cooling capacity, provided that the one heat transfer joining portion 32 extends in the direction orthogonal to the flow direction of the heat-transfer medium.

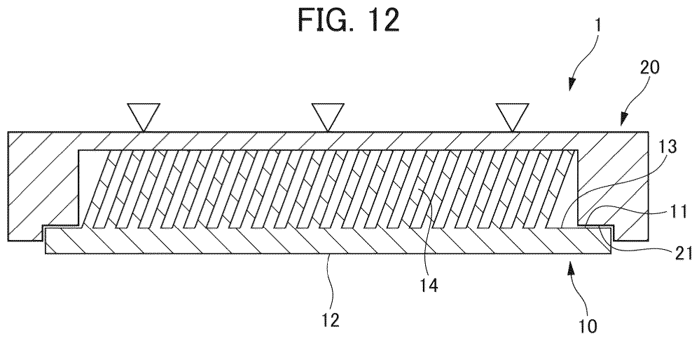

The above embodiment has described that the heat transfer portions 14 extend in a perpendicular direction from the heat dissipation surface 13, but the present disclosure is not limited thereto. The heat transfer portions 14 may extend obliquely from the heat dissipation surface 13 toward the cover plate 20, for example, as illustrated in FIG. 12, provided that the heat transfer portions 14 extend from the heat dissipation surface 13 toward the cover plate 20.

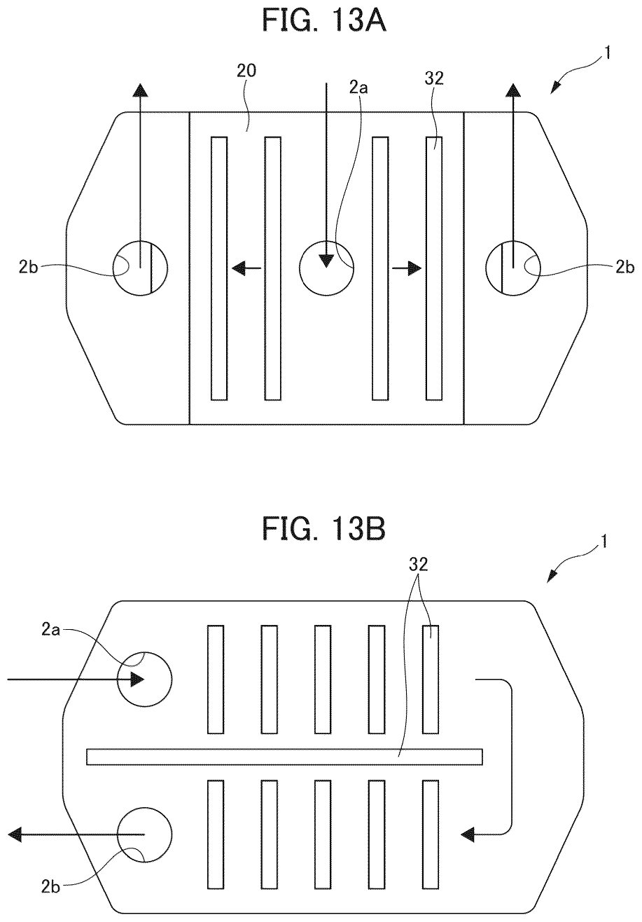

Further, the above-described embodiment has described the case in which the heat-transfer medium flows into the heat-transfer-medium flow space 2 from the heat-transfer medium inlet 2a provided at the end portion in the longitudinal direction of the cover plate 20, and the heat-transfer medium that has flowed through the heat-transfer-medium flow space 2 flows out from the heat-transfer medium outlet 2b provided at the other end portion, but the present disclosure is not limited thereto. For example, as illustrated in FIG. 13A, the heat-transfer medium inlet 2a may be provided at the central portion in the longitudinal direction of the cover plate 20, and the heat-transfer medium outlet 2b may be provided at each of both end portions in the longitudinal direction so that a flow of the heat-transfer medium flowing into the central portion in the longitudinal direction of the heat-transfer-medium flow space 2 branches and flows out from both end portions in the longitudinal direction. For example, as illustrated in FIG. 13B, by disposing the heat-transfer medium inlet 2a and the heat-transfer medium outlet 2b side by side in the width direction at the end portion in the longitudinal direction of the cover plate 20 and by disposing the heat transfer joining portion 32 in the central portion in the width direction so as to extend in the longitudinal direction without reaching the other end portion in the longitudinal direction to partition the heat-transfer-medium flow space 2, it is possible to cause the heat-transfer medium that has flowed in from the end portion in the longitudinal direction to flow to the other end portion in the longitudinal direction and cause the heat-transfer medium that has flowed to the other end portion in the longitudinal direction to flow from the other end portion to the end portion in the longitudinal direction.

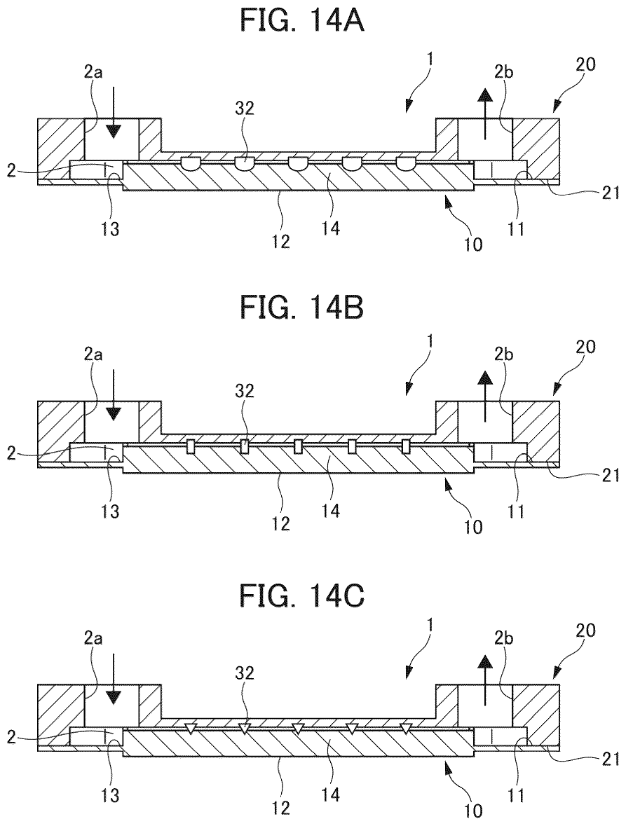

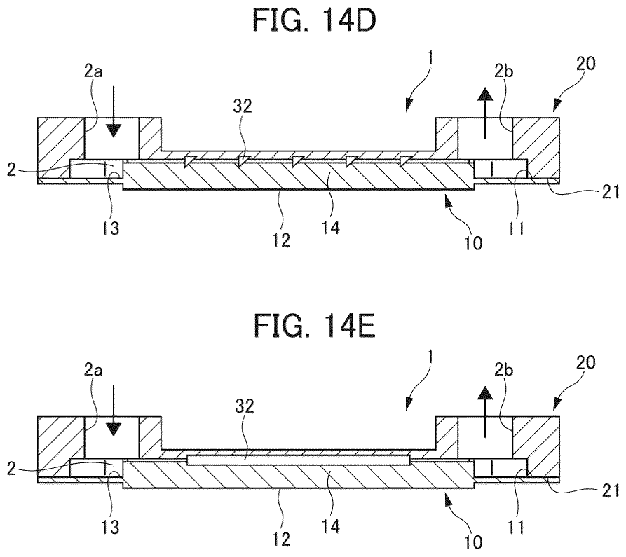

Further, the heat transfer joint portion 32 may be formed in a semicircular cross-sectional shape that protrudes toward the heat-transfer-medium flow space 2 as illustrated in FIG. 14A or may be formed in a rectangular cross-sectional shape that protrudes toward the heat-transfer-medium flow space 2 as shown in FIG. 14B. Further, as illustrated in FIG. 14C and FIG. 14D, the heat transfer joining portion 32 may be formed in a triangular cross-sectional shape that protrudes toward the heat-transfer-medium flow space 2. Furthermore, as shown in FIG. 14E, the heat transfer joint portion 32 may be formed so as to protrude substantially throughout the heat-transfer-medium flow space 2 in the flow direction of the heat-transfer medium.

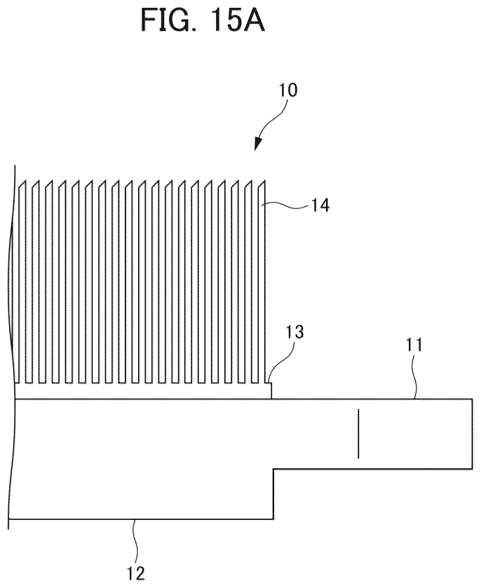

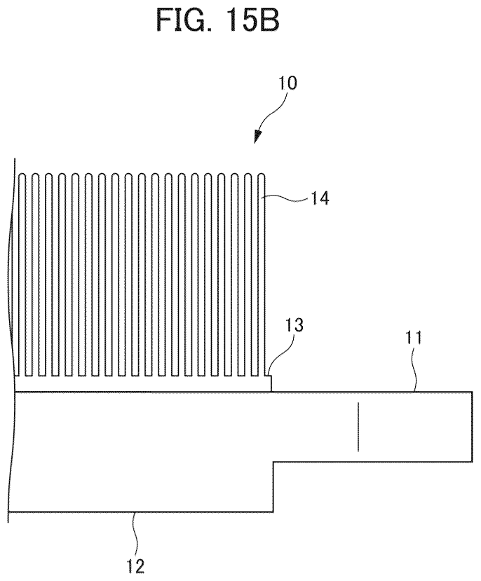

The above-described embodiment has described the heat transfer portions 14 each having a constant width dimension from a base end portion to the tip, with the tip having a flat surface facing the surface of the cover plate 20 facing the heat-transfer-medium flow space 2. For example, as illustrated in FIG. 15A, each heat transfer portion 14 may be formed in a shape in which the tip portion tapers toward the tip, or as illustrated in FIG. 15B, may be formed such that the tip has a curved surface protruding toward a central portion in the thickness dimension T.

The above embodiment has described water as an example of the heat-transfer medium, but the present disclosure is not limited thereto. For example, an antifreeze liquid containing ethylene glycol or a refrigerant gas such as hydrofluorocarbon (HFC) may be used as the heat-transfer medium.

The above-described embodiment has described the plurality of heat transfer portions 14 each configured as a fin that extends in the flow direction of the heat-transfer medium flowing through the heat-transfer-medium flow space 2, but the present disclosure is not limited thereto. The heat transfer portion 14 only has to have a shape protruding from the heat dissipation surface 13 toward the cover plate 20 in the heat-transfer-medium flow space 2, and may, for example, be a conical protrusion protruding from the heat dissipation surface 13 toward the cover plate 20.

The above embodiment has described the cover plate 20 that is joinable to the base plate 10 by laser welding, but the present disclosure is not limited thereto. The cover plate 20 may be joined to the base plate 10 by brazing, diffusion bonding, friction stir welding (FSW), or pressure welding.

The above embodiment has described the heat transfer joining portion 32 formed by performing laser welding, but the present disclosure is not limited thereto. The heat transfer joining portion 32 may be formed by brazing, diffusion bonding, friction stir welding (FSW), or pressure welding.

### EXPLANATION OF REFERENCE NUMERALS

1 cold plate
2 heat-transfer-medium flow space
10 base plate
11 base-side joining portion
12 heat absorbing surface
13 heat dissipation surface
14 heat transfer portion
20 cover plate
31 seal joining portion
32 heat transfer joining portion

1. A cold plate that has therein a heat-transfer-medium flow space, through which a heat-transfer medium flows, and that releases, to the heat-transfer medium flowing through the heat-transfer-medium flow space, heat absorbed from an object to be cooled, the cold plate comprising:
a base plate provided with, on a surface, a heat absorbing surface that absorbs heat released from the object to be cooled and provided with, on another surface, a heat dissipation surface that releases, to the heat-transfer medium flowing through the heat-transfer-medium flow space, the heat absorbed by the heat absorbing surface; and
a cover plate that covers the heat dissipation surface of the base plate, wherein
the heat-transfer-medium flow space is formed between the heat dissipation surface of the base plate and the cover plate,
the base plate has a plurality of heat transfer portions that are provided so as to protrude from the heat dissipation surface toward the cover plate and that transfer, to the heat-transfer medium flowing through the heat-transfer-medium flow space, the heat released from the heat dissipation surface, and
a heat transfer joining portion that joins at least a portion of tips of the plurality of heat transfer portions to the cover plate is formed between at least the portion of the tips of the plurality of heat transfer portions and a surface of the cover plate facing the heat-transfer-medium flow space, and
a flow path of the heat-transfer medium in the heat-transfer-medium flow space is set by the heat transfer joining portion.

2. The cold plate according to claim 1, wherein
each of the plurality of heat transfer portions is configured as a fin that extends along a flow direction of the heat-transfer medium flowing through the heat-transfer-medium flow space.

3. The cold plate according to claim 1, wherein
the base plate has a base-side joining portion provided so as to extend in a circumferential direction of an outer periphery of the base plate,
the cover plate has a cover-side joining portion provided so as to extend in the circumferential direction of an outer periphery of the cover plate, and
a seal joining portion that seals the heat-transfer-medium flow space is formed between the base-side joining portion and the cover-side joining portion.

4. The cold plate according to claim 1, wherein
the base plate and the cover plate are each made of copper, a copper alloy, aluminum, an aluminum alloy, stainless steel, or a stainless-steel alloy.

5. A method of manufacturing a cold plate that has therein a heat-transfer-medium flow space, through which a heat-transfer medium flows, and that releases, to the heat-transfer medium flowing through the heat-transfer-medium flow space, heat absorbed from an object to be cooled, the method comprising:
a plate stacking step of stacking, on a base plate, a cover plate that covers a heat dissipation surface, the base plate being provided with, on a surface, a heat absorbing surface that absorbs heat released from the object to be cooled, being provided with, on another surface, the heat dissipation surface that releases, to the heat-transfer medium flowing through the heat-transfer-medium flow space, heat absorbed by the heat absorbing surface, and being provided with a plurality of heat transfer portions that are provided so as to protrude from the heat dissipation surface toward the cover plate and that transfer, to the heat-transfer medium flowing through the heat-transfer-medium flow space, the heat released from the heat dissipation surface;
a heat transfer joining step of joining, to a surface of the cover plate facing a heat-transfer-medium flow space, a portion of tips of the plurality of heat transfer portions by laser welding in a state in which the cover plate has been stacked on the base plate in the plate stacking step; and
a flow path of the heat-transfer medium in the heat-transfer-medium flow space is set in the heat transfer joining step.

6. The method of manufacturing the cold plate according to claim 5, further comprising:
a heat transfer portion forming step of forming the plurality of heat transfer portions into fin shapes that extend along a flow direction of the heat-transfer medium flowing through the heat-transfer-medium flow space.

7. The method of manufacturing the cold plate according to claim 5, further comprising:
a base-side joining portion forming step of forming a base-side joining portion that is provided so as to extend in a circumferential direction of an outer periphery of the base plate,
a cover-side joining portion forming step of forming a cover-side joining portion that is provided so as to extend in the circumferential direction of an outer periphery of the cover plate, and
a seal joining step of sealing the heat-transfer-medium flow space by joining the base-side joining portion formed in the base-side joining portion forming step and the cover-side joining portion formed in the cover-side joining portion forming step to each other.

8. The method of manufacturing the cold plate according to claim 7, wherein
in the seal joining step, the base-side joining portion and the cover-side joining portion are joined to each other by brazing, diffusion bonding, friction stir welding, or pressure welding.
